(19) United States
(12) Patent Application Publication
(10) Pub. No.: US 2025/0199377 A1
(43) Pub. Date: Jun. 19, 2025

(54) ULTRA-WIDEBAND WHITE NOISE GENERATION APPARATUS BASED ON CHAOTIC MICRO-RING OPTICAL FREQUENCY COMBS

(71) Applicant: GUANGDONG UNIVERSITY OF TECHNOLOGY, Guangdong (CN)

(72) Inventors: Pu LI, Guangdong (CN); Qizhi LI, Guangdong (CN); Qiang CAI, Guangdong (CN); Bingjie XU, Guangdong (CN); Yuncai WANG, Guangdong (CN)

(73) Assignee: GUANGDONG UNIVERSITY OF TECHNOLOGY, Guangdong (CN)

(21) Appl. No.: 19/004,407

(22) Filed: Dec. 29, 2024

Related U.S. Application Data
(63) Continuation of application No. PCT/CN2024/120930, filed on Sep. 25, 2024.

(30) Foreign Application Priority Data
Dec. 15, 2023 (CN) 202311738477.5

(51) Int. Cl. G02F 1/35

(52) U.S. Cl. CPC G02F 1/3538; G02F 2203/15; G02F 2203/54

(57) ABSTRACT

The present invention relates to an on-chip ultra-wideband white noise generation apparatus based on chaotic micro-ring optical frequency combs. The apparatus includes semiconductor lasers, micro-ring resonators, and a photoelectric detector. The semiconductor lasers, the micro-ring resonators, and the photoelectric detector are integrated on a same chip substrate; and after outputting continuous light which is injected into the micro-ring resonators, the semiconductor lasers have a combined effect of four-wave mixing, self-phase modulation, cross-phase modulation, and chromatic dispersion, and after the continuous light is outputted by through ports of the micro-ring resonator, chaotic optical frequency combs at an equal interval are generated, so that a high bandwidth noise signal is achieved by frequency beating of multiple chaotic optical frequency combs. Compared with existing noise generation apparatuses, the present invention features a simple structure and has the advantages of a smaller volume, low power consumption, high stability, and an expandable bandwidth.

### CROSS-REFERENCE TO RELATED APPLICATION

This application is a continuation of International Application No. PCT/CN2024/120930, filed on Sep. 25, 2024, which claims priority to Chinese Patent Application No. 202311738477.5, filed on Dec. 15, 2023. The disclosures of the aforementioned applications are hereby incorporated by reference in their entireties.

### TECHNICAL FIELD

The present invention relates to the technical field of communication and particularly relates to an ultra-wideband white noise generation apparatus based on chaotic micro-ring optical frequency combs.

### BACKGROUND

Noise is a problem that cannot be avoided and needs to be solved in most systems. In an earlier stage of research, people often make efforts in reducing or eliminating noise. With further in-depth research, it is gradually found that noise shows excellent performance in testing the anti-jamming capability of instruments and evaluating the performance of a communication system. By inputting precisely known noise into a device, module or system to be measured, the sensitivity of a receiver can be measured, the performance of an antenna can be evaluated, parameters of an amplifier can be analyzed, an output of a radiometer can be calibrated, and the anti-jamming capability of radar can be inspected. Therefore, a noise generation apparatus is a special scientific instrument with significant use in many fields such as communication, remote sensing, military, astronomy and so on. Moreover, to generate a noise generation apparatus with a high bandwidth, a uniform spectral density, and easy implementation has become an important research field.

At present, most noise generation apparatuses are realized based on a random process of an electronic device. A typical method is to control and amplify noise in physical devices such as a resistor, an avalanche diode, and a field-effect transistor to generate white Gaussian noise. However, by means of this method, noise with the bandwidth in MHz magnitude can only be generated. In addition, for such noise generation apparatuses, an electric amplifier is often needed to amplify the output noise, resulting in a relatively complicated overall system. Moreover, with increase of the bandwidth, the flatness of the output noise is deteriorated.

A noise generation apparatus based on photonics can break through the bottleneck of an electronic bandwidth to generate a noise signal with a wide band. Typical optical noise includes laser phase noise, amplified spontaneous radiation noise and others. In addition, thanks to characteristics of a high bandwidth, a high amplitude, similarity to noise and others, a chaotic laser can also be used as the noise generation apparatus. For example, the phase noise based on a vertical-cavity surface-emitting laser can generate an optical noise signal approximating to 1 GHz [Physical Review E, 2010, 81 (5), 051137]; a wideband noise signal can also be generated by using a superradiant light emitting diode combined with a photoelectric conversion device, with the bandwidth approximating to 12 GHz [Optics Letters, 2011, 36 (6), 1020-1022]; and chaotic laser light generated by optical heterodyning of two semiconductor lasers with external feedback produces a noise signal with a bandwidth of 16.7 GHZ. [Optics Express, 2017, 25 (4), 3153-3164]. Compared with the noise signal generated by an electronic technique, the bandwidth of the noise signal obtained by the noise generation apparatus based on photonics is greatly enhanced.

However, the above apparatus is mostly constructed by a plurality of discrete optical elements, resulting in problems such as a complicated structure, a large size, susceptibility to environmental influences, poor stability, and so on. The generated bandwidth is limited, only around a dozen GHz. Moreover, the bandwidth of the noise does not have expansibility, resulting in limited application of the noise generation apparatus. Therefore, developing a high bandwidth and expandable on-chip noise generation apparatus that is uniform in spectral density, high in stability, and easy to realize is crucial.

### SUMMARY

Overcoming the limitations of current technologies, an object of the present invention is to provide an on-chip ultra-wideband white noise generation apparatus based on chaotic micro-ring optical frequency combs.

The object of the present invention can be realized by using the following technical measure: an on-chip ultra-wideband white noise generation apparatus based on chaotic micro-ring optical frequency combs is designed, including:
a chip substrate, a semiconductor laser array, a micro-ring resonator array, a photoelectric detector, and optical waveguides, where semiconductor laser, micro-ring resonator, and the photoelectric detector all are integrated on the same chip substrate, and the semiconductor laser, the micro-ring resonators, and the photoelectric detector are connected through the optical waveguides. Laser light outputted by the semiconductor lasers is coupled to the micro-ring resonators after being transmitted by the optical waveguides. Thanks to modulation instability and higher-order non-linear effects in the micro-rings, the laser light outputted by the micro-rings generate the chaotic optical frequency combs. The chaotic optical frequency combs are manifested as frequency combs at an equal interval in an optical frequency domain and are manifested as randomly fluctuating chaotic signals in a time domain. Free spectral ranges of the generated chaotic optical frequency combs are changed by designing radii of the micro-ring resonators, such that the free spectral ranges of the chaotic optical frequency combs generated thereby gradually increase in sequence and the chaotic optical frequency combs are finally coupled to a same waveguide for a frequency beating action. The frequency beating among modes occurs to obtain frequency spectra in different frequency bands. The generated frequency spectra are spliced and overlapped with each other, and are finally photoelectrically converted by the photoelectric detector to output the ultra-wideband white noise.

The semiconductor lasers, the micro-ring resonators, the optical waveguides, and the photoelectric detector are integrated on the same chip by way of bonding to realize a hybrid integrated on-chip white noise generation apparatus structure based on the chaotic micro-ring optical frequency combs.

Central wavelengths of the laser light outputted by the semiconductor laser are consistent. A linewidth of the laser light outputted by each of the semiconductor laser is less than a linewidth of a resonant peak of each of the micro-ring resonators to ensure that pump light can be coupled to enter an annular waveguide of each of the micro-ring resonators. Moreover, the central wavelength of the light outputted by each of the laser is less than the wavelength corresponding to the resonant frequency closest thereto, i.e., at a blue detuned site of the resonant peak of each of the micro-ring resonators.

Each of the micro-ring resonators includes any one of structures among an all-pass structure, an ladder structure, a non-concentric structure, and a racetrack structure. The annular waveguide and straight waveguide of each of the micro-ring resonators are made from silicon, lithium niobate, and doped glass with a high refractive index difference. A quality factor Q of each of the micro-ring resonators is greater than 10⁵.

The nonlinear effect in each of the micro-ring resonators includes four-wave mixing, self-phase modulation, cross phase modulation and the like.

The free spectral range of each of the chaotic micro-ring optical frequency combs can be realized by changing the perimeter of each of the micro-ring resonators, and the radii of the micro-ring resonators gradually increase in sequence. The free spectral range of each of the chaotic micro-ring optical frequency combs is calculated and obtained by the following formula:

$$FSR = Δ λ = \frac{{λ}^{2}}{{n}_{g} L} ,$$

where, Δλ represents the free spectral range of each of the micro-ring resonators, λ is the central wavelength of the laser light outputted by each of lasers, n_{g} is a group refractive index of the waveguides of each of the micro-ring resonators, and L is the perimeter of each of the micro-ring resonators.

The chaotic micro-ring optical frequency combs with different free spectral ranges are coupled to the same waveguide, the frequency beating occurs among the modes to generate white noise with corresponding center frequencies, the center frequencies of the white noise are decided by a frequency difference of the corresponding modes, and the white noise with different center frequencies is spliced with each other to finally generate the ultra-wideband white noise. Besides, the number of the chaotic optical frequency combs and the number of comb teeth of the chaotic optical frequency combs are increased for frequency beating among more modes, such that the bandwidth of the white noise can be further improved finally.

The on-chip ultra-wideband white noise generation apparatus based on chaotic micro-ring optical frequency combs provided by the present invention has the following advantages and positive effects:

1. The technical solution provides a hybrid integrated on-chip white noise generation apparatus, where chaotic micro-ring optical frequency combs are introduced, and the micro-ring resonators, the semiconductor laser, the optical waveguides, and the photoelectric detector are integrated on the same chip and are connected through the optical waveguides. Compared with a technical solution with discrete elements, the noise generation apparatus features a simple structure and has the advantages of a smaller volume, low power consumption stability, and high stability.

2. The technical solution generates the wideband white noise by using an optical method, and effectively avoids the bottleneck of the electronic bandwidth by means of the photoelectric conversion method; and by increasing the number of the chaotic micro-ring optical frequency combs and the number of comb teeth of the single optical frequency comb, white noise with a higher bandwidth is generated, so that the noise generation apparatus has expandability.

### BRIEF DESCRIPTION OF DRAWINGS

FIG. 1 is a schematic structural diagram of an on-chip ultra-wideband white noise generation apparatus based on chaotic micro-ring optical frequency combs provided by the present invention.

FIG. 2 is a spectral schematic diagram of a single chaotic optical frequency comb of an ultra-wideband white noise generation apparatus based on chaotic micro-ring optical frequency combs provided by the present invention.

FIG. 3 is a spectral schematic diagram of a single mode of ten chaotic optical frequency combs of an ultra-wideband white noise generation apparatus based on chaotic micro-ring optical frequency combs provided by the present invention.

FIG. 4 is a schematic diagram of a power spectrum result of an on-chip ultra-wideband white noise generation apparatus based on chaotic micro-ring optical frequency combs provided by the present invention.

### DETAILED DESCRIPTION OF EMBODIMENTS

The technical measures of the present invention will be further described in detail below in conjunction with special implementations to make those skilled in the art recognize the objects, advantages, and technical measures of the present invention more clearly. Apparently, the described embodiments are merely some rather than all of the embodiments of the present invention. Based on the practical cases in the present invention, any other practical cases obtained by other technical staff in the art without making creative effects all can be incorporated into the protection scope of the present invention.

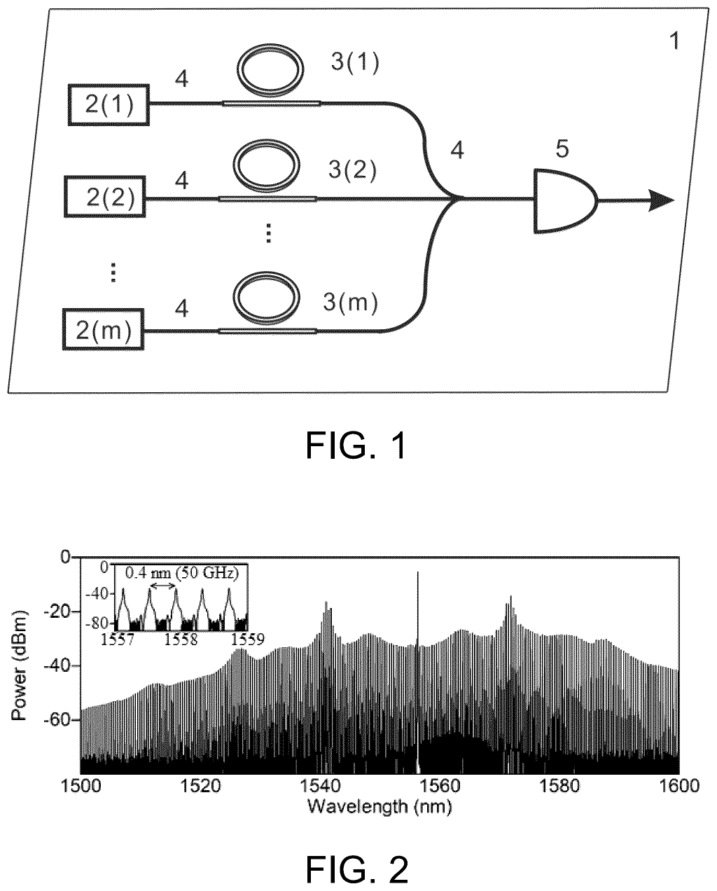

As shown in FIG. 1, an ultra-wideband white noise generation apparatus based on chaotic micro-ring optical frequency combs provided by the present invention structurally includes: a chip substrate 1, semiconductor laser 2, micro-ring resonators 3, optical waveguides 4, and a photoelectric detector 5.

The semiconductor laser 2, the micro-ring resonators 3, the optical waveguides 4, and the photoelectric detector 5 all are integrated on the chip substrate 1. Laser light outputted by the semiconductor laser 2 are coupled as pump light to the micro-ring resonators 3, and thanks to modulation instability and higher-order non-linear effects in the micro-rings, the chaotic optical frequency combs are generated. The devices are connected through the optical waveguides 4 to transmit optical signals in the whole light path. After the micro-ring resonators 3 generate m chaotic micro-ring optical frequency combs with different free spectral ranges which are transmitted and gathered to one path through the waveguides, the frequency beating occurs among corresponding longitudinal modes to generate frequency spectra in different frequency bands, and the interval between the frequency spectra is decided by the frequency difference between the comb teeth in each path. By properly selecting the optical frequency difference of each frequency band, the frequency bands finally generated with different center frequencies are spliced with each other, and finally, the photoelectric detector 5 outputs the ultra-wideband white noise.

By setting the pump light of the chaotic micro-ring optical frequency combs as a 0 mode, two modes adjacent to the pump light are respectively defined as a +1 mode and a −1 mode. Taking frequency beating between single modes (+1 modes) of two chaotic micro-ring optical frequency combs as an example, assuming that the central wavelengths of the two modes are respectively λ₁ and λ₂, the beat frequency is produced between the two modes to generate white noise in the two frequency bands. The central frequency of one frequency band is at a direct component, and the central frequency fₜₕ of another frequency band is decided by the optical frequency difference between the two modes and can be shown as fₜₕ=c/λ₁−c/λ₂. The frequency beating effect between the modes corresponds to a convolution in the principle, and a photo-generated current i(t) of the photoelectric detector can be in principle as a convolution between a detector response function r(t) and two light fields E₁(t) and E₂(t) of two laser light: i(t)=r(t)*[E̅₁̅(̅t̅)̅E₁(t)+E̅₂̅(̅t̅)̅E₂(t)]. Therefore, the power spectrum S(f) of an electric signal outputted by the detector is represented as: S(f)=| [symbol] {i(t)}|²=|R(f)|²×[S(v₁)*S(v₁)+S(v₂)*S(v₂)+25 (v₁)*S(v₂)], where S(v₁) represents a spectral concentration of the first mode, and S(v₂) represents a spectral concentration of the second mode. v₁ and v₂ are respectively the central frequencies of the two modes.

Specifically, taking a silicon optical chip as a substrate, the semiconductor lasers, the micro-ring resonators, the optical waveguides, and the photoelectric detector are integrated on the chip by way of bonding. Each of the micro-ring resonators is of the all-pass structure and is prepared by doped glass with a high refractive index difference. A range of a Q value of the micro-ring is 2×10⁶−3×10⁶. As shown in FIG. 2, each of the chaotic micro-ring optical frequency combs is a broadband optical source composed of a series of discrete laser modes equally spaced. Hundreds of modes are included in a range of 1500 nm-1600 nm, and adjacent longitudinal modes are spaced by 0.4 nm. The central wavelength of each of the longitudinal modes (except the pump light) of each of the chaotic micro-ring optical frequency combs can be adjusted by changing the radius of each of the micro-ring resonators. After m chaotic micro-ring optical frequency combs with different central wavelengths are transmitted and coupled to one waveguide through m waveguides, the frequency beating effect among the modes to generate the frequency spectra with corresponding central frequencies. The central frequency of the frequency spectra is decided by the frequency difference between the modes. The generated frequency spectra are spliced with each other to finally generate the ultra-wideband white noise.

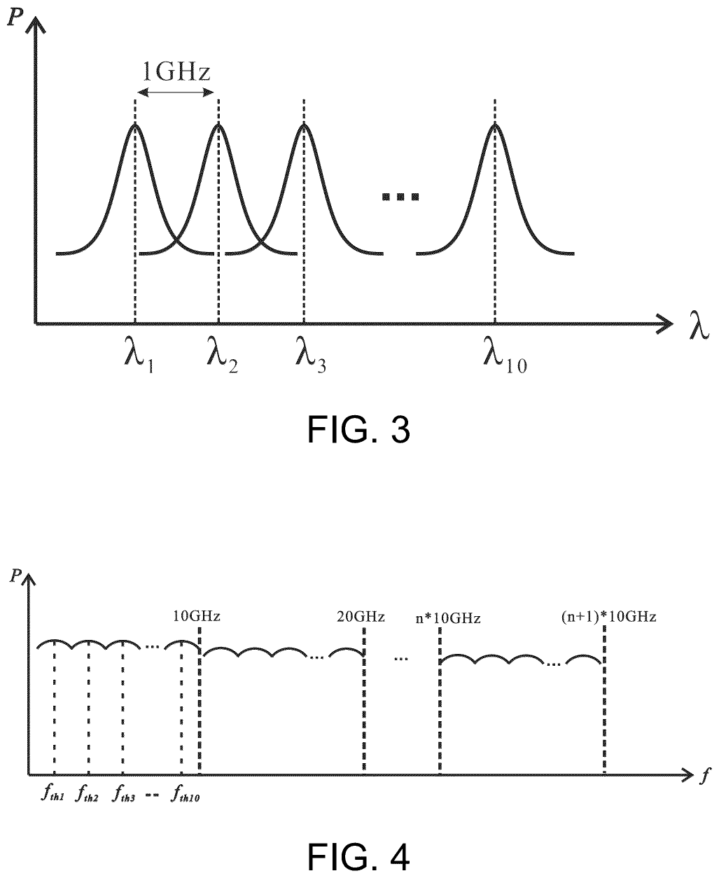

Specifically, ten chaotic micro-ring optical frequency combs are taken as an example. The central wavelengths of the laser light outputted by the semiconductor lasers all are 1553 nm. By changing the radii of the micro-ring resonators, the free spectral ranges of the generated ten chaotic micro-ring optical frequency combs are 41 GHz, 42 GHz, . . . , 50 GHz in sequence. As shown in FIG. 3, the frequency differences between the first modes (λ₁, λ₂, . . . , λ₁₀) of the ten chaotic micro-ring optical frequency combs all are 1 GHz. White noise in ten frequency bands are generated after the beating frequency among the ten modes are photoelectrically converted by the photoelectric detector. The central frequencies in the frequency bands are increased by 1 GHz in sequence, so that white noise with the bandwidth being 10 GHz (10×1 GHz) can be generated. The frequency differences between the second modes (λ₁₁, λ₁₂, . . . , λ₂₀) all are 2 GHz. The central frequencies in the corresponding generated frequency bands are increased by 2 GHz in sequence. The frequency differences between the frequencies (λ₁₀ₙ₊₁, λ₁₀ₙ₊₂, . . . λ₁₀ₙ₊₁₀) of the n^{th} mode all are n GHz, and the central frequencies in the corresponding generated frequency bands are increased by n GHz in sequence. The frequency bands with different center frequencies are spliced with each other to finally generate the wideband white noise. As the coverage range of the chaotic micro-ring optical frequency combs can reach hundreds of nm, where n can reach 100 above. If the number m of paths and the number n of comb teeth of the chaotic optical frequency combs are increased, white noise with a wider bandwidth can be generated, as shown in FIG. 4.

It is to be particularly noted that the on-chip ultra-wideband white noise generation apparatus based on chaotic micro-ring optical frequency combs generates white noise through photoelectric conversion and by utilizing the frequency beating effect of the multiple chaotic micro-ring optical frequency combs. The spectral range of the chaotic micro-ring optical frequency combs can reach hundreds of nm, including hundreds of modes. Therefore, the frequency beating in the multiple chaotic micro-ring optical frequency combs may achieve the wideband white noise. By introducing the chaotic micro-ring optical frequency combs, and integrating the micro-ring resonators, the semiconductor lasers, the optical waveguides, and the photoelectric detector on the same chip and connecting them through the optical waveguides, an on-chip white noise generation apparatus featuring a compact structure, a high integration level, and a small size is obtained. Compared with the prior art, the white noise generation apparatus is relatively simple in structure and has the advantages of high stability and low power consumption. By increasing the number of the chaotic micro-ring optical frequency combs and the number of comb teeth of the single optical frequency comb, the white noise generation apparatus can greatly improve the bandwidth of the white noise and has expandability.

The above is merely preferred embodiments of the present invention and does not hence limit the patent scope of the present invention. Equivalent structure or equivalent flow conversion made by means of the contents of the description and drawings of the present invention or equivalent structure or equivalent flow conversion applied to other related technical fields directly or indirectly, which is, in a similar way, comprised in the protection scope of the patent of the present invention.

What is claimed is:

1. An ultra-wideband white noise generation apparatus based on chaotic micro-ring optical frequency combs, comprising m semiconductor lasers, micro-ring resonators consistent with the semiconductor lasers in quantity, and a photoelectric detector, wherein the semiconductor lasers, the micro-ring resonators, and the photoelectric detector all are integrated on a same chip substrate, and the semiconductor lasers, the micro-ring resonators, and the photoelectric detector are connected through optical waveguides with each other; the semiconductor lasers outputs continuous light, and the continuous light is injected into the micro-ring resonators through transmission of the optical waveguide, the continuous light has a combined effect of a series of non-linear effects and chromatic dispersion in the micro-ring resonators, resulting in spectrum widening; chaotic optical frequency combs at an equal interval are outputted via through ports of the micro-ring resonator; a radius of the micro-ring resonators is designed to generate the chaotic optical frequency combs with different free spectral ranges, the chaotic optical frequency comb generated in each of the micro-ring resonators is coupled to one waveguide and is then inputted into the photoelectric detector, and finally, an ultra-wideband white noise is outputted from the photoelectric device.

2. The ultra-wideband white noise generation apparatus based on chaotic micro-ring optical frequency combs according to claim 1, wherein a central wavelength of a laser light outputted by each of the semiconductor lasers is at a blue detuned site of a harmonic peak of each of the micro-ring resonators, i.e., a pump wavelength is less than a wavelength corresponding to a resonant frequency closest to the pump wavelength.

3. The ultra-wideband white noise generation apparatus based on chaotic micro-ring optical frequency combs according to claim 1, wherein a linewidth of the laser light outputted by each of the semiconductor lasers is less than a linewidth of the resonant peak of each of the micro-ring resonators.

4. The ultra-wideband white noise generation apparatus based on chaotic micro-ring optical frequency combs according to claim 1, wherein a structure of each of the micro-ring resonators is selected from an all-pass structure, a ladder structure, a non-concentric structure, or a racetrack structure.

5. The ultra-wideband white noise generation apparatus based on chaotic micro-ring optical frequency combs according to claim 1, wherein the laser light outputted by each of the semiconductor lasers is injected into each of the micro-ring resonators to have the combined effect of four-wave mixing, self-phase modulation, cross-phase modulation, and chromatic dispersion.

6. The ultra-wideband white noise generation apparatus based on chaotic micro-ring optical frequency combs according to claim 1, wherein the free spectral range of each of the chaotic optical frequency combs is capable of being regulated and controlled by changing the radius of each of the micro-ring resonators, the free spectral ranges of the multiple chaotic optical frequency combs generated increase gradually in sequence, and frequency detuning among corresponding modes of the chaotic optical frequency combs increases gradually; and the free spectral range of each of the chaotic micro-ring optical frequency combs is calculated and obtained by following formula:
$$FSR = Δλ = \frac{{λ}^{2}}{{n}_{g} L} ,$$
wherein Δλ represents a free spectral range of each of the micro-ring resonators, λ is a central wavelength of the laser light outputted by each of the lasers, n_{g} is a group refractive index of the waveguides of each of the micro-ring resonators, and L is a perimeter of each of the micro-ring resonators.

7. The ultra-wideband white noise generation apparatus based on chaotic micro-ring optical frequency combs according to claim 1, wherein after the multiple chaotic optical frequency combs are gathered to one waveguide, different modes of frequency detuning beat frequency to generate a white noise with a corresponding center frequency, and frequency spectra generated is capable of being spliced with each other to finally output the ultra-wideband white noise.

8. The ultra-wideband white noise generation apparatus based on chaotic micro-ring optical frequency combs according to claim 1, wherein a number of paths of the chaotic optical frequency combs and a number of comb teeth of the chaotic optical frequency combs are increased to generate a white noise with a higher bandwidth.
